(19) United States
(12) Patent Application Publication
(10) Pub. No.: US 2015/0136598 A1
(43) Pub. Date: May 21, 2015

(54) Glass Coating System

(71) Applicant: CSG HOLDING CO., LTD., Shenzhen City (CN)

(72) Inventors: Haifeng Chen, Shenzhen City (CN); Shaohua Jiang, Shenzhen City (CN); Shiwu Xie, Shenzhen City (CN); Zhenzhong Bai, Shenzhen City (CN)

(21) Appl. No.: 14/475,729

(22) Filed: Sep. 3, 2014

(30) Foreign Application Priority Data
Nov. 20, 2013 (CN) 201310588999.1

(51) Int. Cl. C23C 14/34

(52) U.S. Cl. CPC C23C 14/34
USPC 204/298.24

(57) ABSTRACT

A system for coating a sheet of glass is disclosed. The system includes a first coating chamber, a second coating chamber, an intermediary chamber and three conveying units. The intermediary chamber is sandwiched between the first and second chambers and has a gap plate and an elevator connected to the gap plate. The three conveying units are separately disposed in lower portions of the first costing chamber, the second coating chamber and the intermediary chamber for conveying a sheet of glass to be coated. The gap plate is located above one of the conveying units, and the elevator is capable of adjusting a distance between the gap plate and the conveying unit.

### BACKGROUND OF THE INVENTION

1. Technical Field The invention relates to coating devices, particularly to glass coating systems.

2. Related Art

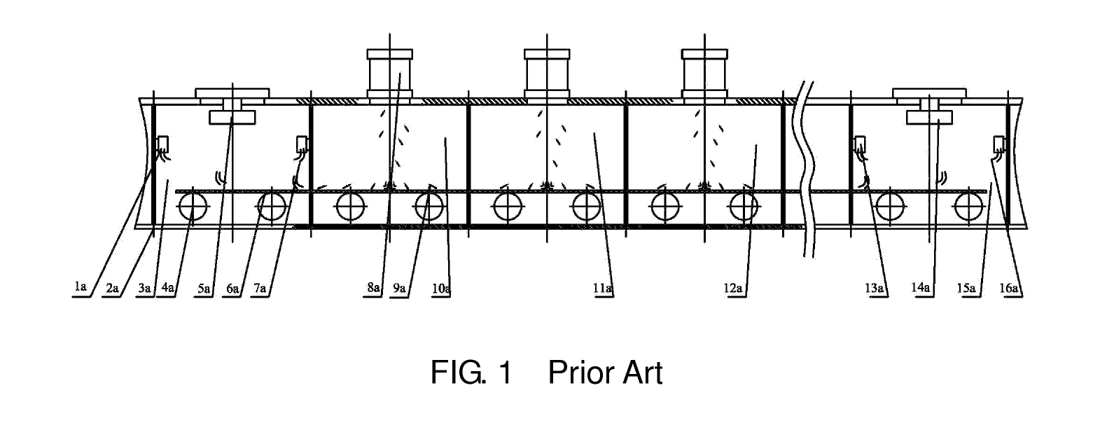

In recent years, with the execution of national policy of energy conservation and carbon reduction, energy-saving glass has been applied in doors, windows and glass curtain extensively. As shown in FIG. 1, in a coating production line for energy-saving glass, two adjacent cathodes must be filled with different reaction gases 7a, 16a for reaction coating. To guarantee the purity of reaction coating, the gases 7a, 16a cannot communicate with and permeate through each other. This needs a long distance between the two adjacent cathodes. Usually, such a distance is 6-8 times as long as a cathode chamber. Additionally, each chamber must be equipped with one or two vacuum pumps to pump gas out. This makes a production line become very long and occupy a large space and manufacture costs will increase.

In a conventional production line for energy-saving glass as shown in FIG. 1, when a vacuum room 2a is pumped out by a vacuum pump 8a to a certain vacuum degree, a reaction gas 7a is filled in the chamber 3a through a gas supply tube la, and the cathode 5a in the chamber 3a starts working to perform reaction sputtering. A sheet of glass 6a to be coated is conveyed under the cathode 5a to be formed with a film. This is vacuum coating. Similarly, when the glass is conveyed to the chamber 15a by a roller, a reaction gas 16a is filled in the chamber 15a through a gas supply tube 13a, and the cathode 14a in the chamber 15a starts working to perform reaction sputtering. Thus, the glass is coated with another film. To guarantee the gases separately in the chambers 3a, 5a do not communicate with and permeate through each other, there must be an intermediary chamber 10a and a vacuum pump 8a so that a part of the gas 7a will be pumped out when it permeate through the intermediary chamber 10a. Similarly, if the intermediary chambers are enough in number, such as the reference numbers 11a and 12a, this will guarantee that the gases separately in the chambers 3a, 15a do not communicate with and permeate through each other. This also means that a length of the whole production line needs to be enlarged, the quantity of the vacuum pumps must be increased, and the cost of the production line must be increased.

### SUMMARY OF THE INVENTION

An object of the invention is to provide a glass coating system, which can guarantee the gases separately in different chambers not to communicate with and permeate through each other without prolonging the distance between two cathodes.

Another object of the invention is to provide a glass coating system, which can continuously coat glass with different thickness without a pause.

To accomplish the above objects, the glass coating system of the invention includes a first coating chamber, a second coating chamber, an intermediary chamber and three conveying units. The intermediary chamber is sandwiched between the first and second chambers and has a gap plate and an elevator connected to the gap plate. The three conveying units are separately disposed in lower portions of the first costing chamber, the second coating chamber and the intermediary chamber for conveying a sheet of glass to be coated. The gap plate is located above one of the conveying units, and the elevator is capable of adjusting a distance between the gap plate and the conveying unit.

In the present invention, by the adjustable intermediary chamber between the first and second chambers, the distance between the two cathodes does not need to be prolonged and the gases separately in different chambers cannot communicate with and permeate through each other. This can shorten the distance between two cathodes. Also, the invention has an advantage of continuous adjustment in vacuum. When different kinds of glass with different thickness are being processed, a pause in production is not needed. Only adjusting the gap plate in vacuum to fit different glass thickness is enough. The invention can be applied in continuous glass coating production lines.

### BRIEF DESCRIPTION OF THE INVENTION

FIG. 1 is a schematic view of a conventional glass coating device;

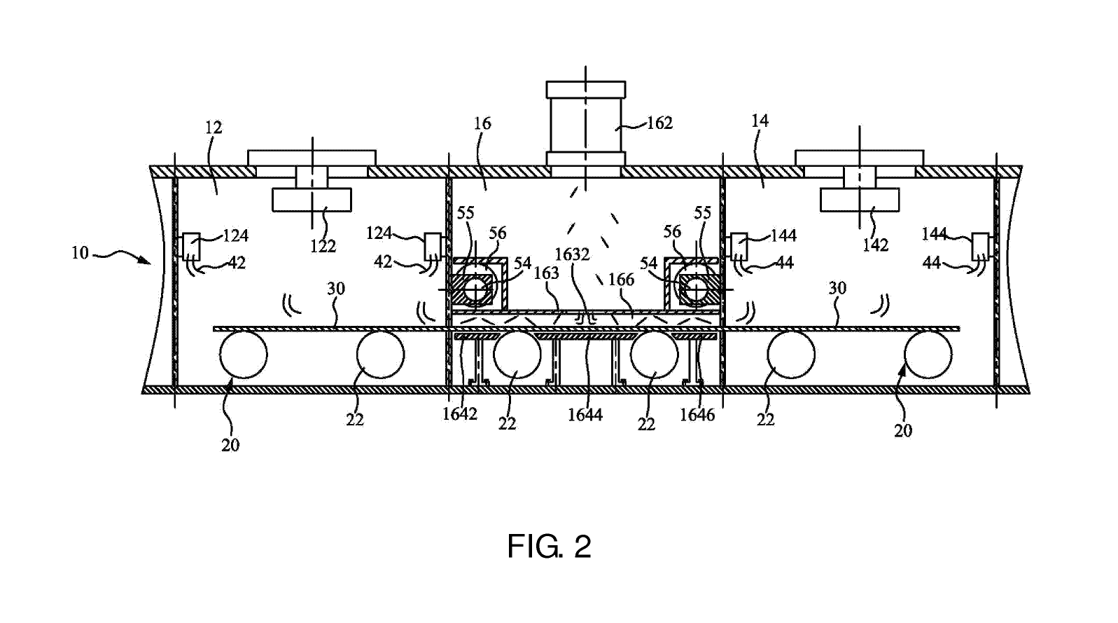

FIG. 2 is a sectional view of the invention; and

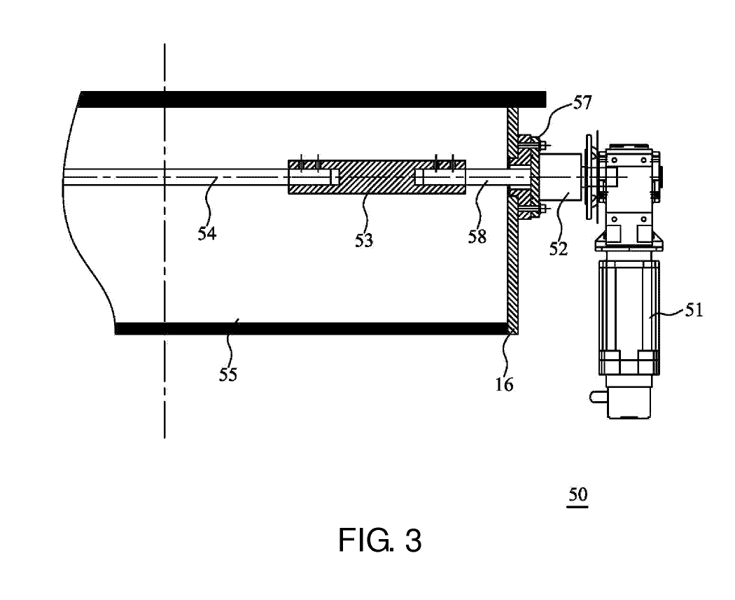

FIG. 3 is a schematic view of the elevator of the invention.

### DETAILED DESCRIPTION OF THE INVENTION

Please refer to FIGS. 2 and 3. The invention provides a glass coating system for coating a sheet of glass 30. The system includes a first coating chamber 12, an intermediary chamber 16, a second coating chamber 14 and three conveying units 20. The intermediary chamber 16 is located between the first and second coating chambers 12, 14. The conveying units 20 are separately located at lower portions of the first coating chamber 12, the intermediary chamber 16 and the second coating chamber 14 for conveying the glass 30 to be coated. The intermediary chamber 16 has a gap plate 163 and an elevator 50 connected to the gap plate 163. The gap plate 163 is located above one of the conveying units 20. The elevator 50 is capable of adjusting a distance between the gap plate 163 and the conveying unit 20. In a coating process, the relative distance which can be adjusted is a gap 166. When the glass 30 to be coated varies in thickness, the coating process can be performed without a pause.

The elevator 50 includes a servomotor 51 and an eccentric wheel mechanism. The servomotor 51 is disposed outside the intermediary chamber 16. The eccentric wheel mechanism connects the gap plate 163. A spindle 58 of the servo motor 51 is provided with a coupling 54. The eccentric wheel mechanism includes a bearing seat 55 on a side wall of the intermediary chamber 16. A shaft 54 is disposed in the bearing seat 55. The shaft 54 is disposed with an eccentric wheel 56. The shaft 54 is connected to the spindle 58 through the coupling 53. The eccentric wheel 56 connects the gap plate 163. The gap plate 163 can be moved up or down by rotation of the spindle 58 of the servomotor 51 so as to adjust the distance between the gap plate 163 and the conveying unit 20. When a vacuum degree in the first coating chamber 12, the intermediary chamber 16 and the second coating chamber 14 reaches the sputtering vacuum degree, the servomotor 51 is started to rotate with a certain angle, and the spindle 58, the shaft 54 and the eccentric wheel 56 are driven to rotate. The position of the eccentric wheel 56 makes the distance between the gap plate 163 and a left bottom 1642, a middle bottom 1644 and a right bottom 1646 become smaller to form the gap 166.

A sealing ring 57 is disposed between the spindle 58 of the servomotor 51 and the intermediary chamber 16. A sealing element 52 is disposed between the spindle 58 and the sealing ring 57. The sealing ring 57 and the sealing element 52 divide the spindle 58 into an interior portion and an exterior portion to guarantee the vacuum degree of the first coating chamber 12, the intermediary chamber 16 and the second coating chamber 14.

The elevator 50 may be two in number and they are separately mounted on two sides of the gap plate 163 for higher stability and accuracy.

The conveying unit 20 in the intermediary chamber 16 includes two parallel rollers 22. The two rollers 22 divide the bottom of the intermediary chamber 16 into a left bottom 1642, a middle bottom 1644 and a right bottom 1646. The bottom is not protrudent from the highest points of the rollers 22.

The first and second coating chambers 12, 14 are separately provided with two cathodes 122, 142 above the conveying units 20 and two gas supply tubes 124, 144. The gas supply tubes 124, 144 are filled with reaction gases 42, 44. The intermediary chamber 16 is provided with a vacuum pump 162 above the conveying unit 20. The vacuum pump 162 may be a molecular pump or a pumping tube of another vacuum pump.

The gap plate 163 is formed with a pumping aperture 1632 under the vacuum pump 162 for pumping a small amount of the reaction gasses 42, 44 to prevent the gasses 42, 44 from entering the second coating chamber 14.

As shown in FIGS. 2 and 3, the coating method of the invention includes a first step of starting the vacuum pump 162 in the intermediary chamber 16 to pumping air out. The system includes a first coating chamber 12, an intermediary chamber 16, a second coating chamber 14 and three conveying units 20. The intermediary chamber 16 is located between the first and second coating chambers 12, 14. The conveying units 20 are separately located at lower portions of the first coating chamber 12, the intermediary chamber 16 and the second coating chamber 14 for conveying the glass 30 to be coated. The intermediary chamber 16 has a gap plate 163 and an elevator 50 connected to the gap plate 163. The gap plate 163 is located above one of the conveying units 20. The elevator 50 is capable of adjusting a distance between the gap plate 163 and the conveying unit 20.

A second step is to place the glass 30 to be coated on the conveying unit 20.

1) When a vacuum degree in the first coating chamber 12, the intermediary chamber 16 and the second coating chamber 14 reaches the sputtering vacuum degree, the servomotor 51 is started to rotate with a certain angle, and the spindle 58, the shaft 54 and the eccentric wheel 56 are driven to rotate. The position of the eccentric wheel 56 makes the distance between the gap plate 163 and a bottom form the gap 166.

2) Fill the gas supply tube 124 in the first coating chamber 12 with the reaction gas 42, and the cathode 122 of the first coating chamber 12 starts sputtering. Then fill the gas supply tube 142 in the second coating chamber 14 with the reaction gas 44, and the cathode 142 of the second coating chamber 14 starts sputtering.

3) Convey the glasses 30 to be coated into the first coating chamber 12, the intermediary chamber 16 and the second coating chamber 14 one by one. When the first sheet of glass 30 nears the left bottom 1642, start the servomotor 51 to adjust the distance between the gap plate 163 and the glass 30 to be less than 1 mm

4) Repeat the above steps to coat another glass when a glass 30 has been coated. The position of the eccentric wheel 56 makes the distance between the gap plate 163 and a bottom form the gap 166. When the distance is adjusted to be less than 1 mm, the first and second coating chambers 12, 14 are under the sputtering vacuum degree and the mean free path will be much greater than the distance. According to the theory of molecular movement in vacuum, the gas molecular is hard to pass the gap. Thus the reaction gasses 42, 44 in the first and second coating chambers 12, 14 can be isolated. The gap plate 163 is formed with a pumping aperture 1632 under the vacuum pump 162 for pumping a small amount of the reaction gasses 42, 44 to prevent the gasses 42, 44 from entering the second coating chamber 14. Thus, using a shorter distance to isolate reaction gases 42, 44 is achieved. Similarly, the gap plate 163 can be adjusted downward to reduce the distance when no glass 30 exists. Under the sputtering vacuum degree, the mean free path will be much greater than the distance. According to the theory of molecular movement in vacuum, the gas molecular is hard to pass the gap. Thus the reaction gasses 42, 44 in the first and second coating chambers 12, 14 can be isolated.

In a coating process, the relative distance which can be adjusted is a gap. When the glass to be coated varies in thickness, the coating process can be performed without a pause.

In the present invention, by the adjustable intermediary chamber between the first and second chambers, the distance between the two cathodes does not need to be prolonged and the gases separately in different chambers cannot communicate with and permeate through each other. This can shorten the distance between two cathodes. Also, the invention has an advantage of continuous adjustment in vacuum. When different kinds of glass with different thickness are being processed, a pause in production is not needed. Only adjusting the gap plate in vacuum to fit different glass thickness is enough. The invention can be applied in continuous glass coating production lines.

Those skilled in the art will appreciate that numerous changes and modifications can be made to the preferred embodiment of the invention, and that such changes and modifications can be made without departing from the spirit of the invention.

What is claimed is:

1. A glass coating system comprising:
a first coating chamber;
a second coating chamber;
an intermediary chamber, sandwiched between the first and second chambers, and having a gap plate and an elevator connected to the gap plate; and
three conveying units, separately disposed in lower portions of the first costing chamber, the second coating chamber and the intermediary chamber for conveying a sheet of glass to be coated;
wherein the gap plate is located above one of the conveying units, and the elevator is capable of adjusting a distance between the gap plate and the conveying unit.

2. The glass coating system of claim 1, wherein the elevator comprises a servomotor and an eccentric wheel mechanism, the servomotor 51 is disposed outside the intermediary chamber, the eccentric wheel mechanism connects the gap plate 163, and s spindle of the servo motor is provided with a coupling.

3. The glass coating system of claim 2, wherein the eccentric wheel mechanism comprises a bearing seat on a side wall of the intermediary chamber, a shaft 54 is disposed in the bearing seat, the shaft is disposed with an eccentric wheel, the shaft is connected to the spindle through the coupling.

4. The glass coating system of claim 3, wherein the eccentric wheel connects the gap plate, the gap plate is moved up or down by rotation of the spindle of the servomotor so as to adjust the distance between the gap plate and the conveying unit.

5. The glass coating system of claim 2, wherein a sealing ring is disposed between the spindle of the servomotor and the intermediary chamber, and a sealing element is disposed between the spindle and the sealing ring.

6. The glass coating system of claim 2, wherein the elevator is two in number, and the two elevators are separately mounted on two sides of the gap plate.

7. The glass coating system of claim 2, wherein the conveying unit in the intermediary chamber comprises two parallel rollers, the two rollers divide a bottom of the intermediary chamber into a left bottom, a middle bottom and a right bottom, and the bottom is not protrudent from highest points of the rollers.

8. The glass coating system of claim 1, wherein the first and second coating chambers are separately provided with two cathodes above the conveying units and two gas supply tubes, the gas supply tubes are filled with reaction gases, and the intermediary chamber is provided with a vacuum pump above the conveying unit.

9. The glass coating system of claim 8, wherein the gap plate is formed with a pumping aperture under the vacuum pump.
